(19) United States
(12) Patent Application Publication
(10) Pub. No.: US 2013/0056793 A1
(43) Pub. Date: Mar. 7, 2013

(54) PROVIDING GROUP V AND GROUP VI OVER PRESSURE FOR THERMAL TREATMENT OF COMPOUND SEMICONDUCTOR THIN FILMS

(71) Applicant: SWAMINATHAN T. SRINIVASAN, Pleasanton, CA (US)

(72) Inventor: SWAMINATHAN T. SRINIVASAN, Pleasanton, CA (US)

(73) Assignee: Applied Materials, Inc., Santa Clara, CA (US)

(21) Appl. No.: 13/589,355

(22) Filed: Aug. 20, 2012

Related U.S. Application Data
(60) Provisional application No. 61/531,885, filed on Sep. 7, 2011.

(51) Int. Cl. H01L 21/20; H01L 29/267

(52) U.S. Cl. 257/183; 438/478; 257/E21.09; 257/E29.081

(57) ABSTRACT

Embodiments of the invention provide methods for forming high quality, low resistivity Group III-V or Group II-VI compounds. In one embodiment, the method includes growing a compound semiconductor layer having a n-type or p-type dopant over a substrate, the compound semiconductor layer comprising at least a first component and a second component, and the second component has a vapor pressure relatively higher than the first component, forming a supplemental layer consisted essentially of the second component at or near an upper surface of the compound semiconductor layer, and anneal the substrate. A capping layer may be formed on the supplemental layer to help prevent loss of crystallinity of the second component at elevated temperatures. An overpressure of the second component gas may be provided onto an exposed surface of the substrate during annealing to enhance the surface morphology of the compound semiconductor layer.

### CROSS-REFERENCE TO RELATED APPLICATIONS

This application claims benefit of U.S. provisional patent application Ser. No. 61/531,885, filed Sep. 7, 2011, which is herein incorporated by reference.

### BACKGROUND OF THE INVENTION

1. Field of the Invention

Embodiments of the present invention generally relate to processes for forming low resistivity Group III-V or Group II-VI compound semiconductors with high doping concentration at or near the surface of Group III-V or Group II-VI compound semiconductors.

2. Description of the Related Art

Group III-V or II-V compounds are finding greater importance in the development and fabrication of a variety of semiconductor devices, such as light emitting diodes (LEDs), laser diodes (LDs), and logic circuit devices such as field effect transistors (FETs). In these devices, a plurality of semiconductor layers having different mixed crystal compositions are layered together to obtain intended optical and electrical characteristics.

However, growing a low resistivity, high quality p-type Group III-V compound on a substrate of a different material, such as a sapphire substrate or a silicon substrate, with a desired doping profile has been unsatisfactory. Taking GaN as an example, the Group V element (i.e., nitrogen) which has a relatively high vapor pressure tends to be volatile when the GaN crystal is heated at elevated temperatures to activate implanted dopant species therein, leading to decomposition of the GaN through loss of nitrogen (i.e., nitrogen vacancies) in the GaN lattice. If surface decomposition occurs, the crystallinity of compound semiconductors tends to be degraded. While surface decomposition can be suppressed or at least reduced by providing an overpressure of nitrogen in a thermal annealing chamber, utilization of overpressure undesirably increases the cost of ownership since it would require high ambient concentration in the gas surrounding the substrate along with safety related containment and monitoring.

In addition, efforts to dope the GaN film p-type have been unsuccessful since GaN is naturally an n-type doped semiconductor material with high carrier concentration. The n-type characteristic is attributed in part to nitrogen vacancies in the crystal structure which are formed as a result of GaN decomposition at elevated temperatures as discussed above. Therefore, a suitable p-type dopant species such as magnesium (Mg) is typically introduced during the GaN growth to obtain a p-type doped GaN. Many devices require a free carrier concentration in the p-type doped GaN of at least 10¹⁸ cm⁻³; however, Mg-doped GaN is suffering from insufficient carrier concentration since the effect of a dopant impurity (e.g., Mg) is greatly reduced by high amount of nitrogen vacancies as discussed above and in most situations is “neutralized” or “inactivated” by unintentional H passivation due to the formation of Mg—H complexes (if NH₃ gas is used during the process to contribute the N component). Therefore, only a few percent of Mg dopant atoms are activated, which contributes to non-ideal tradeoffs in structure, composition, and device performance.

Therefore, there is a need for an improved method for depositing high quality, high activated doping of compound semiconductors with low cost thermal treatment approach.

### SUMMARY OF THE INVENTION

The present invention generally provide methods for forming high quality, low resistivity Group III-V or Group II-VI compounds with high concentration of Group V or VI material formed at or near the surface of Group III-V or Group II-VI compounds to help prevent loss of crystallinity of Group V or VI elements at or near the surface. In one embodiment, a method of manufacturing a compound semiconductor includes growing a compound semiconductor layer having a n-type or p-type dopant over a substrate, the compound semiconductor layer comprising at least a first component and a second component, wherein the second component has a vapor pressure relatively higher than the first component, forming a supplemental layer consisted essentially of the second component at or near an upper surface of the compound semiconductor layer, and subjecting the substrate to an annealing process. The compound semiconductor layer may be n-type or p-type Group III-V or Group II-VI compound semiconductors. In one example, a capping layer may be optionally formed on the supplemental layer to help prevent loss of crystallinity of the second component at elevated temperatures. An overpressure of the second component gas may be provided onto an exposed surface of the substrate during annealing to enhance the surface morphology of the compound semiconductor layer.

In another embodiment, a method of manufacturing a compound semiconductor includes epitaxially growing a compound semiconductor layer having a p-type dopant over a substrate, the compound semiconductor layer comprising at least a first component and a second component, wherein the second component has a vapor pressure relatively higher than a vapor pressure of the first component, forming a supplemental layer consisted essentially of the second component at or near an upper surface of the compound semiconductor layer, and annealing the substrate with an overpressure of the second component gas provided onto an exposed surface of the substrate. In one example, the supplemental layer is formed by a plasma immersion implantation or a plasma doping process. The annealing may be performed by directing a plurality of pulses of electromagnetic energy at the compound semiconductor layer for a period of time that is sufficient to recrystallize the compound semiconductor layer.

In yet another embodiment, a method of manufacturing a compound semiconductor includes growing a Group III-V compound semiconductor layer over a substrate, forming a p-type doping layer on an upper surface of the Group III-V compound semiconductor layer, forming a supplemental layer consisted essentially of Group V material on the p-type doping layer, forming a capping layer on the supplemental layer, and subjecting the substrate to an annealing process. In one example, an overpressure of the second component gas onto an exposed surface of the substrate during annealing to enhance the surface morphology of the Group III-V compound semiconductor layer.

In one another embodiment, a compound semiconductor device is provided. The device includes a Group III-V compound semiconductor layer deposited over a substrate, a p-type doping layer deposited on an upper surface of the Group III-V compound semiconductor layer, a supplemental layer consisted essentially of Group V material deposited on the p-type doping layer, and a capping layer deposited on the supplemental layer. In one example, the Group III-V compound semiconductor layer may include GaN, GaAs, InSb, InAs, InP, GaSb, GaP, or AlSb.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates a schematic isometric view of a laser anneal apparatus that is adapted to perform an annealing process described within an embodiment herein.

FIG. 1B illustrates a schematic side view of the apparatus of FIG. 1A.

FIG. 2A illustrates a schematic cross-sectional view of a substrate formed by a process sequence according to one embodiment of the present invention.

FIG. 2B illustrates a schematic cross-sectional view of a substrate formed by a process sequence according to another embodiment of the present invention.

FIG. 3 illustrates a process sequence used to form the substrate depicted in FIG. 2A or 2B according to the present invention.

### DETAILED DESCRIPTION

Embodiments disclosed herein generally provide methods for forming high quality, low resistivity Group III-V or Group II-VI compounds with high concentration of Group V or VI material formed at or near the surface of Group III-V or Group II-VI compounds to help prevent loss of crystallinity of Group V or VI elements at or near the surface at elevated temperatures. The surface morphology and the lattice quality may be improved by use of a capping layer deposited on top of the high concentration of Group V or VI material and additionally an overpressure of Group V or VI material gas provided onto the exposed surface of the substrate during a subsequent annealing process to prevent surface decomposition or other stoichiometric degradation of the crystal near the surface of the Group III-V or II-VI compound layer.

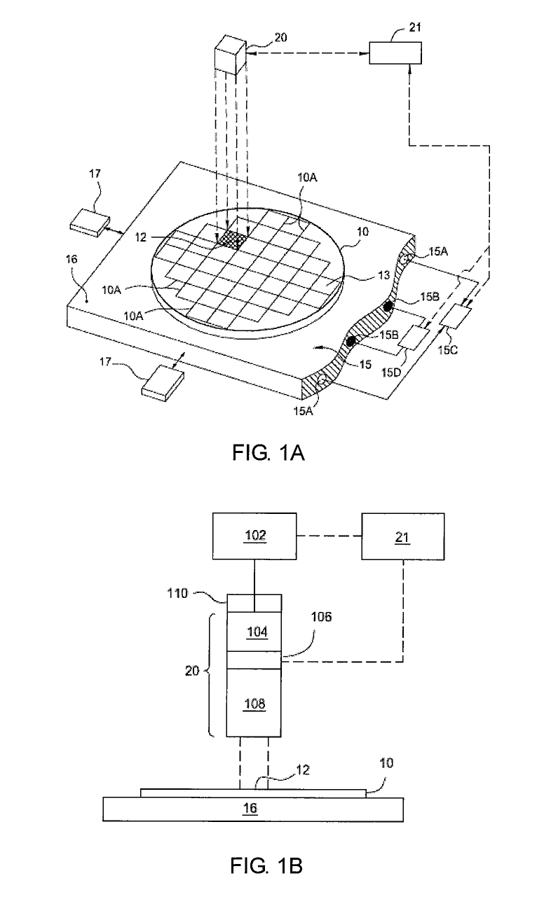

FIG. 1A illustrates an isometric view of one embodiment of the invention that may be used to benefit the present invention. In one embodiment, an energy source 20 is adapted to project an amount of energy on a defined region, or an anneal region 12, of the substrate 10 to preferentially anneal certain desired regions within the anneal region 12. In one embodiment, as shown in FIG. 1A, only one or more defined regions of the substrate, such as anneal region 12, are exposed to the radiation from the energy source 20 at any given time. In one aspect of the invention, a single area of the substrate 10 is sequentially exposed to a desired amount of energy delivered from the energy source 20 to cause preferential annealing of desired regions of the substrate. Typically, one or more conventional electrical actuators 17 (e.g., linear motor, lead screw and servo motor), which may be part of a separate precision stage (not shown), are used to control the movement and position of substrate 10.

In one aspect shown in FIG. 1A, the anneal region 12, and radiation delivered thereto, is sized to match the size of the die 13 (e.g., 40 “die” are shown in FIG. 1), or semiconductor devices (e.g., memory chip), that are formed on the surface of the substrate. In one aspect, the boundary of the anneal region 12 is aligned and sized to fit within the “kerf” or “scribe” lines 10A that define the boundary of each die 13. Sequentially placing anneal regions 12 so that they only overlap in the naturally occurring unused space/boundaries between die 13, such as the scribe or kerf lines, reduces the need to overlap the energy in the areas where the devices are formed on the substrate and thus reduces the variation in the process results between the overlapping anneal regions. In one example, the area of each of the sequentially placed anneal regions 12 formed on the surface of the substrate is between about 4 mm² (e.g., 2 mm×2 mm) and about 1000 mm² (e.g., 25 mm×40 mm). It is contemplated that the size and shape of the edges of the anneal regions 12 is adjustable upon the need of processing schemes.

The energy source 20 is generally adapted to deliver electromagnetic energy to preferentially anneal certain desired regions of the substrate surface. Typical sources of electromagnetic energy include, but are not limited to, an optical radiation source (e.g., laser or flash lamps), an electron beam source, an ion beam source, and/or a microwave energy source. In one example, the multiple pulses of energy from the energy source 20 are tailored so that the amount of energy delivered across the anneal region 12 and/or the amount of energy delivered over the period of the pulse is optimized so as not to melt, or nearly melt the anneal region or a crystalline seed region that has been previously deposited on the substrate surface, but to deliver enough energy to promote epitaxial re-growth, for example, the amorphous layer, progressively from the surface of the crystalline seed region. Therefore, a significant portion of the crystalline seed region underneath the annealed regions is activated and propagates throughout the amorphous layer, thereby recrystallizing the amorphous layer deposited thereabove.

In one embodiment, the wavelength of the energy source 20 is tuned so that a significant portion of the radiation is absorbed by a layer disposed on the substrate 10. For an anneal process performed on a silicon containing layer, for example, the wavelength of the radiation may be less than about 800 nm, and can be delivered at deep ultraviolet (UV), infrared (IR) or other desirable wavelengths. In one embodiment, the energy source 20 is an intense light source, such as a laser, that is adapted to deliver radiation at a wavelength between about 500 nm and about 11 micrometers. In another embodiment, the energy source 20 may be a tungsten halogen lamp or a flash lamp featuring a plurality of radiation-emitting lamps, such as xenon, argon, or krypton discharge lamps. In all cases, the energy pulse used in the anneal process generally takes place over a relatively short time, such as on the order of about 1 nsec to about 10 msec.

FIG. 1B is a schematic side view of the apparatus of FIG. 1A. A power source 102 is coupled to the energy source 20. The energy source 20 may include an energy generator 104, which may be a light source such as those described above, and an optical assembly 108. The energy generator 104 is configured to produce energy and direct it into the optical assembly 108, which in turn shapes the energy as desired for delivery to the substrate 10. The optical assembly 108 generally includes lenses, filters, mirrors, and the like that are configured to focus, polarize, de-polarize, filter or adjust coherency of the energy produced by the energy generator 104, with the objective of delivering a uniform column of energy to the anneal region 12.

In order to deliver pulses of energy, the energy generator 104 may contain a pulsed laser, which is configurable to emit light at a single wavelength or at two wavelengths simultaneously. In one embodiment the energy generator 104 may include a Nd:YAG laser, with one or more internal frequency converters that cause a laser head to emit light at different laser frequency. Alternatively, the energy generator 104 may be configured to emit three or more wavelengths simultaneously, or further alternatively or additionally, to provide a wavelength-tunable output. In one example, the laser head used in the energy generator 104 is Q-switched to emit short, intense pulses, with pulse duration ranging, for example, from 1 nanosecond to 1 second.

In order to realize pulsed lasers, the apparatus may contain a switch 106. The switch 106 may be a fast shutter that can be opened or closed in 1 μsec or less. Alternately, the switch 106 may be an optical switch, such as an opaque crystal that becomes clear in less than 1 μsec when light of a threshold intensity impinges on it. The optical switch generates pulses by interrupting a continuous beam of electromagnetic energy directed toward a substrate. The switch is operated by a controller 21, and may be located inside, or outside the energy generator 104, such as coupled to or fastened to an outlet area of the energy generator 104. The controller 21 may be configured to switch the power source 102 on and off as needed, or a capacitor 110 may be provided such that it is charged by the power source 102 and discharged into the energy generator 104 by virtue of circuitry energized by the controller 21. Electrical switching by capacitor is a way of self-switching, because the energy generator 104 stops generating energy when electricity provided by the capacitor 110 falls below a certain power threshold. When the capacitor 110 is recharged by the power source 102, it can then be discharged into the energy generator 104 to generate another pulse of energy. In some embodiments, the electrical switch may be configured to switch power on or off in less than 1 nsec.

In one embodiment, it may be desirable to control the temperature of the substrate during thermal processing by placing a surface of the substrate 10, as illustrated in FIG. 1A, in thermal contact with a substrate supporting surface 16 of a heat exchanging device 15. The heat exchanging device 15 is generally adapted to heat and/or cool the substrate prior to or during the annealing process to improve the post-processing properties of the annealed regions of the substrate. In general, the substrate 10 is placed within an enclosed processing environment (not shown) of a processing chamber (not shown) that contains the heat exchanging device 15. The processing environment within which the substrate resides during processing may be evacuated or contain a gas suitable to the desired process. For example, embodiments of the present invention may be used in deposition or implant processes that require certain gases be provided to the chamber. In one aspect shown in FIG. 1A, the heat exchanging device 15 contains resistive heating elements 15A and a temperature controller 15C that are adapted to heat a substrate disposed on a substrate supporting surface 16. The temperature controller 15C may be in communication with the controller 21.

In another embodiment, it may be desirable to cool the substrate during processing to reduce any inter-diffusion due to the energy added to the substrate during the annealing process. In processes requiring incremental melting of the substrate, cooling afterward may increase regrowth velocity, which can increase the amorphization of the various regions during processing. The heat exchanging device 15 may contain one or more fluid channels 15B and a cryogenic chiller 15D that are adapted to cool a substrate disposed on a substrate supporting surface 16. In one aspect, a conventional cryogenic chiller 15D, which is in communication with the controller 21, is adapted to deliver a cooling fluid through the one or more fluid channels 15B.

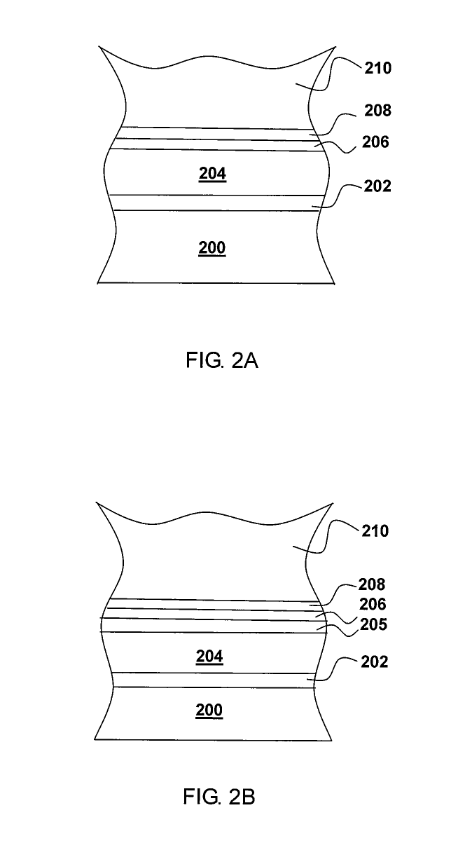

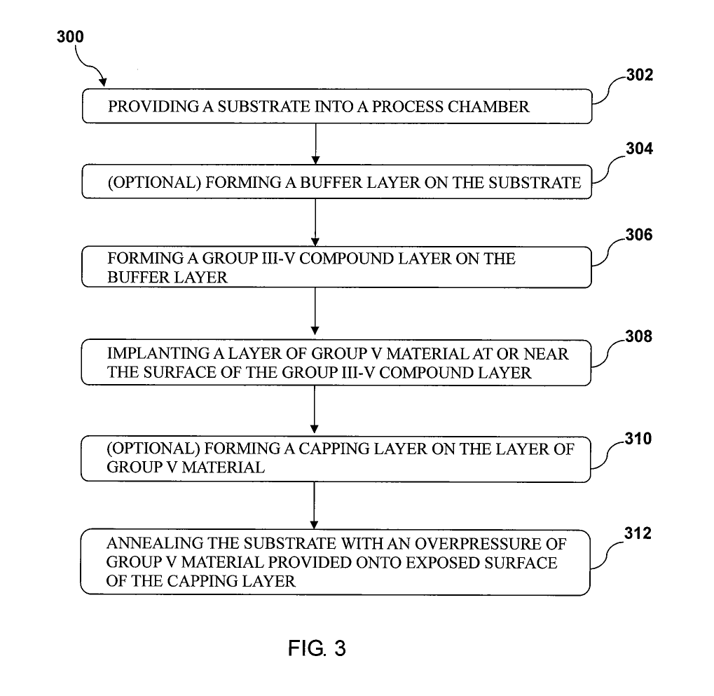

FIG. 2A illustrates a schematic cross-sectional view of a substrate 200 formed by a process sequence shown in FIG. 3. FIG. 3 illustrates a process sequence 300 used to form the substrate depicted in FIG. 2A according to one embodiment of the present invention. In this disclosure, a p-type Group III-V compound, for example GaN, is discussed. However, it is contemplated that the similar concept is applicable to n-type GaN or any other Group III-V compound semiconductors (such as, for example, GaAs, InSb, InAs, InP, GaSb, GaP, or AlSb etc.) or Group II-VI compound semiconductors (such as, for example, ZnS, ZnSe, ZnTe, CdS, CdSe, CdTe, or BeO, etc.), including binary, ternary, and quaternary alloys thereof, or growth of other semiconductors on dissimilar substrates for improvement of film properties.

The process sequence 300 begins at step 302 by providing a substrate 200 in a processing chamber. The substrate 200 may be any suitable substrate, such as a single crystal substrate, upon which a P-doped Group III nitride epitaxial film may be formed. Substrate size may range from about 50 mm to about 100 mm in diameter or larger. Substrates that may be used for embodiments of the invention may include, but are not limited to, sapphire (Al₂O₃), silicon (Si), silicon carbide (SiC), lithium aluminum oxide (LiAlO₂), lithium gallium oxide (LiGaO₂), zinc oxide (ZnO), gallium nitride (GaN), aluminum nitride (AlN), quartz, glass, gallium arsenide (GaAs), indium phosphorus (InP), spinel (MgAl₂O₄), any combination thereof, any mixture thereof, or any alloy thereof. If desired, the substrate surface may be patterned (not shown) using any known method such as masking and etching techniques. In one example, the substrate 200 is a (0001) patterned sapphire substrate (PSS).

At step 304, an optional buffer layer (sometimes referred to as nucleation layer) 202 may be deposited on the sapphire substrate 200. The buffer layer 202 may be any suitable Group III-V compound materials such as gallium nitride (GaN), which can be formed using a reaction precursor containing at least a metal halide gas at a temperature range between about 100° C. and about 600° C. for about 1 minute and about 10 minutes. The metal halide gas may be formed by reacting a halogen containing gas with a Group III metal. The halogen containing gas may be a halide gas. In some examples, the halogen containing gas may include fluorine gas (F₂), chlorine gas (Cl₂), bromine gas (Br₂), iodine gas (I₂), hydrogen fluoride gas (HF), hydrogen chloride gas (HCl), hydrogen bromide gas (HBr), hydrogen iodide gas (HI), or mixtures and combinations thereof. The group III metals may be gallium, aluminum, indium, or a mixture, combination, or alloy thereof. The halogen containing gas flows across a reservoir containing the group III metal, which may be liquid or solid. The gas reacts with the metal to form a metal halide gas, which is used as a reaction precursor in forming the buffer layer 202.

Due to material differences between the sapphire substrate and Group III-nitride layers, such as the lattice constant, thermal expansion coefficient, and interfacial surface energy, the use of the buffer layer may alleviate these differences by providing on the sapphire substrate a certain density of nucleation sites which facilitate the transition of crystallographic and thermal properties between the sapphire substrate and lateral growth of subsequent layers, reducing the tendency of layers to delaminate. In this embodiment, the nucleation sites may be achieved using a selective growth process or other suitable techniques to grow a thin amorphous or polycrystalline GaN in the form of 3-D crystal islands on the sapphire substrate. Once the buffer layer in the form of crystal islands have been created on the sapphire substrate, the reaction precursor may be resumed in the presence of nitrogen plasma or using any suitable thermal treatment at elevated temperatures between about 700° C. and about 1000° C. to recrystallize the buffer layer 202 such that adjacent islands of the GaN material merge or coalesce. As the process continues, the lateral growth of GaN material results in an uncoalesced, good crystalline structure of GaN film, which may serve as a crystal seed, and eventually a desired thickness of mono-crystalline GaN film (e.g., Group III-V compound layer 204 in step 306) can be epitaxially grown on the buffer layer 202.

It is contemplated that the buffer layer 202 may be a binary, ternary or quaternary film comprising a solid solution of one or more Group III elements and nitrogen. For example, the buffer layer 202 may be AlN, AlGaN, InGaN, or InAlGaN (undoped or doped with an n-type or p-type dopant element depending upon application), using a metal organic chemical vapor deposition (MOCVD), hydride vapor phase epitaxial (HVPE), physical vapor deposition (PVD), chemical vapor deposition (CVD), and/or atomic layer deposition (ALD) processes, or any other suitable process. If desired, the buffer layer 202 can be any crystalline film which has a similar lattice structure with the Group III-Nitride crystalline film that is to be formed thereon. It should be noted that the buffer layer 202 may not be required if layers are grown on a GaN substrate or other substrates which are close in their properties to GaN.

At step 306, a Group III-V compound layer 204 is formed on the buffer layer 202. The Group III-V compound layer 204 may be a Group III nitride layer doped n-type or p-type by incorporating the proper impurities, or even undoped, depending upon the application. In one example, the Group III-V compound layer 204 is a p-type GaN using any suitable p-type dopant such as, but not limited to Mg, Be, Ca, Sr, or any suitable Group I or Group II element having at least two valence electrons. While not discussed here, it is contemplated that the Group III-V compound layer 204 can be an n-type doped Group III nitride using any suitable n-type dopant such as Si, Ge, Sn, Pb, or any suitable Group IV, Group V, or Group VI element.

The dopant species may be formed in the Group III-V compound layer 204 using a suitable technique such as an ion implantation process or a thermal deposition/diffusion process. In cases where the thermal deposition is adapted, a MOCVD or HVPE process may be used to form the p-type Group III-V compound layer 204. In one embodiment, the Group III-V compound layer 204 is a p-type GaN doped with magnesium (Mg) epitaxially grown on the buffer layer 202 by a MOCVD process using a gas mixture containing precursor gases such as trimethylgallium (Ga(CH₃)₃; TMG) and nitrogen (or ammonia), and a dopant gas, for example, biscyclopentadienyl magnesium (Cp₂Mg), at a temperature range between about 100° C. and about 800° C., for example about 300° C. to about 700° C. In certain examples, the use of lower temperature deposition (e.g., around 400° C.) may be advantageous as it lowers the overall thermal budget for re-growth or selective re-growth of crystal. It is contemplated that other organometallic precursor may be used. For example, the precursor may include an alkyl Group III metal compound such as an alkyl aluminum compound, an alkyl gallium compound, and/or an alkyl indium compound, among others. Specific precursor examples may include, but are not limited to trimethylaluminum (TMA), triethyl-aluminum (TEA), trimethylindium (TMI), triethylindium (TEI), and triethylgallium (TEG). During the growth, the underlying buffer layer 202, which is in a mono-crystalline structure of GaN, may serve as a seed crystal for growing the p-type GaN layer. Mg as a p-type impurity may be doped in the GaN epitaxial layer while the dopant gas, e.g., Cp₂Mg is flowed into the process chamber, thereby growing the Group III-V compound layer 204 (i.e., the p-type GaN epitaxial layer) to have a film thickness of about 20 to about 5000 nm.

In an alternative embodiment, the p-type Group III-V compound layer 204 may be obtained by conformally or selectively forming a metal layer 205 consisting essentially of p-type dopants, such as magnesium, on the Group III-V compound layer 204, as shown in FIG. 2B. The p-type dopants are then diffused from the metal layer 205 into the underlying Group III-V compound layer 204 during the subsequent annealing process. In either case, the p-type Group III-V compound layer 204 is formed on the buffer layer 202 with an activated concentration of magnesium of about 1×10¹⁷ cm⁻³ or above and may have a total concentration of magnesium atoms of about 1×10²⁰ cm⁻³.

At step 308, an ion implantation process is performed to implant a predetermined concentration of Group V materials at or near the surface of the Group III-V compound layer 204, forming a high concentration of Group V material region 206. It is contemplated that the choice of the dopant to be implanted depends on the epitaxial layer being implanted. In the case of a p-type GaN doped with magnesium (Mg), nitrogen atoms may be implanted into the p-type GaN. As discussed previously, the vapor pressure of the Group V element is orders of magnitude greater than that of the Group III element; it is therefore believed, without being limited to any particular theory, that a high concentration of Group V elements presented at the surface of the Group III-V compound layer 204 helps to prevent decomposition of the GaN surface through loss of Group V element (i.e., nitrogen) or other stoichiometric degradation of the crystal during the subsequent annealing process while permitting diffusion of the nitrogen atoms into the underlying Group III-V compound layer 204 during the subsequent annealing process.

The high concentration of Group V materials may be conformally implanted into the exposed surface of the Group III-V compound layer 204. Alternatively, the dopant species may be selectively implanted into the exposed surface of the Group III-V compound layer 204 by masking, depending upon the application. In order to provide a high concentration of dopant profile at or near the surface of the Group III-V compound layer 204, a convention beam line ion implanter or a plasma immersion implantation (P3i) toroidal source plasma reactor may be used. One suitable reactor chamber which the implantation process may be practiced is a P3i® reactor chamber, available from Applied Materials, Inc., of Santa Clara, Calif. In one example, nitrogen atoms are implanted into the exposed region of the p-type GaN at an ion implantation energy of about 5 keV to about 5000 keV to obtain a total concentration of about 10¹¹ ions/cm² to about 10²¹ ions/cm². The nitrogen atoms may be implanted to a depth (thickness) of between about 5 nm and about 5000 nm from the upper surface of the Group III-V compound layer 204. If desired, the implantation process may be carried out in a plurality of implantation cycles until a desired concentration of the dopants is obtained. While the ion implantation process is described herein, it is contemplated that the Group V materials may be provided at or near the surface of the Group III-V compound layer 204 by other suitable techniques such as plasma doping process or any conventional deposition process.

At step 310, a capping layer 208 is optionally formed on the high concentration of Group V material region 206 before annealing so as to further prevent decomposition of the GaN compound during the subsequent annealing. The capping layer 208 may be made of an arbitrary material as long as it is formable on the high concentration of Group V material region 206, and stable at an elevated temperature during the subsequent annealing process, for example, about 400° C. or higher. The capping layer 208 may include, but is not limited to SiN, SiO₂, Si, GaN, or AlN. In one example, the capping layer 208 is an AlN material which is formed by a PVD process. In such a case, the AlN material may be deposited on the high concentration of Group V material region 206 by reactively sputtering the Al in an argon (Ar) and nitrogen (N₂) gas mixture that is maintained at a reduced pressure, such as an environment maintained at about 0.5 mTorr to several Torr, for example, about 2 mTorr to about 300 Torr. Alternatively, the AlN material may be deposited on the high concentration of Group V material region 206 by RF and/or DC biasing an aluminum nitride (AlN) target in an argon (Ar) and/or nitrogen (N₂) environment to sputter the AlN material on to the surface of the high concentration of Group V material region 206. It is also contemplated that the AlN material may be deposited by evaporating aluminum (Al) in a nitrogen (N₂) rich environment, or even by forming the AlN layer using a CVD method. In various embodiments, the capping layer 208 is formed to a thickness between about 5 nm to about 5000 nm.

At step 312, the substrate 200 is subjected to an annealing process to remove the implantation-induced defects as well as to activate the dopant species (i.e., Mg) in the Group III-V compound layer 204. The annealing process may be any high temperature thermal annealing process that is capable of removing radiation damage and moving the dopant species onto proper substitutional lattice sites of GaN at an annealing temperature of about 900° C. or above, for example, about 1100° C. to about 1300° C. Due to a low dissociation temperature (around 800° C. or above) of N, the required annealing temperature should be reached very fast and the duration of anneal should be limited to a relatively short time, such as on the order of about one second or less, or at sub microsecond duration, to preserve the surface morphology and the lattice quality of GaN. Therefore, it may be advantageous to use a rapid thermal annealing process or a pulsed laser annealing process to melt and recrystallize the Group III-V compound layer 204.

The pulsed laser annealing process as described herein may be performed using the laser anneal apparatus shown in FIGS. 1A and 1B by delivering electromagnetic radiation energy in a series of sequential pulses of energy to allow for a controlled diffusion of dopants and/or removal of implantation damage over a short distance within desired regions of a target layer or substrate. The short distance may be between about one lattice plane to tens of lattice planes. The amount of energy delivered during a single pulse is typically short enough to provide an average diffusion depth that is only a portion of a single lattice plane and thus the annealing process may require multiple pulses to achieve a desired amount of dopant diffusion or lattice damage correction. The substrate 200 may be exposed to multiple pulses of energy from a laser that emits radiation at one or more appropriate wavelengths for a desired period of time. The intensity and wavelength may be tuned depending on the depth of the dopant atoms and the amount of movement desired. Wavelengths of energy used may range generally from the microwave, for example about 3 cm, through visible wavelengths, into the deep ultraviolet, for example about 150 nanometers (nm). Wavelengths ranging from about 300 nm to about 1100 nm, for example, may be used in laser applications, such as wavelengths less than about 800 nm.

During the pulsed annealing process, each successive pulse constitutes a micro-anneal cycle in which energy is delivered at and propagated through the target layer (e.g., the Group III-V compound layer 204) to epitaxially grow the ordered region upward from the ordered region beneath the anneal region toward the surface of the substrate, and therefore smooth the dopant concentration profile. If desired, the intensity and wavelength may be tuned so that each successive pulse is delivered to the buffer layer 202, which is in the crystalline structure of GaN and therefore may serve as seed for recrystallization. Since each pulse is sufficiently short and the additive effects of each pulse is localized and will not cause temperature to rise in the substrate, decomposition of the Group V element does not occur. Rather, the surface morphology is further controlled by the presence of the high concentration of Group V material region 206 and the capping layer 208 (if used) formed on the Group III-V compound layer 204. Particularly, the nitrogen atoms from the high concentration of Group V material region 206 may also diffuse into the underlying Group III-V compound layer 204 (i.e., the p-type GaN) during annealing, thereby compensating or remedying nitrogen vacancies in the Group III-V compound layer 204.

In various embodiments of the present invention, each pulse of the pulsed laser annealing process may deliver an energy density of about 0.2 J/cm² to about 100 J/cm² at a power level of at least 10 milliWatts (mW), such as between about 10 mW and 10 W, and the number of sequential pulses may vary between about 30 and about 100,000 pulses, each of which has a duration of about 1 nanosecond (nsec) to about 10 milliseconds (msec). The duration of each pulse may be less than 10 msec, such as between about about 1 msec and about 10 msec, or between about 1 nsec and about 10 microseconds (μsec), or even less than about 100 nsec. In some examples, duration of each pulse may be between about 1 nsec and about 10 nsec, such as about 1 nsec.

During the annealing process, an overpressure of a high volatile component gas may be provided onto the exposed surface of the substrate, for example, the high concentration of Group V material region 206 or the capping layer 208 (if used), to further enhance the surface morphology and the lattice quality of the underlying Group III-V compound layer 204. In cases where the Group III-V compound layer 204 is GaN, the high volatile component gas may be nitrogen (N₂) gas. While the high volatile component gas using ammonia (NH₃) is also contemplated, it may be less advantageous since atomic hydrogen (H⁺) produced by the pyrolysis of ammonia may be diffused into the underlying Group III-V compound layer 204 and incorporated in a complex with the Mg acceptors in the Group III-V compound layer 204, rendering the Mg acceptors electrically inactive.

While not discussed here, after step 312, one or more device layers 210 may be formed over the high concentration of Group V material region 206 or on the capping layer 208 (if used) to form, for example, a p-n junction which is necessary for the fabrication of the desired semiconductor device, such as light emitting diodes (LEDs), laser diodes (LDs), or other electronic applications such as transistors. It is contemplated that the process of the present invention is suitable for use with more sophisticated structures. Such structures may include those that use one or more quantum wells as active layers, or superlattice structures as part of the crystal transition between the sapphire substrate and the Group III-V layers, for example.

It has been observed that a high quality activated p-type GaN doped with magnesium (Mg) can be obtained using the process sequence described above. Particularly, the incorporation of high concentration of Group V material at or near the surface of Group III-V compound layer prevents surface decomposition or other stoichiometric degradation of the crystal near the surface of the Group III-V compound layer. In addition, the use of an additional capping layer on top of the high concentration of Group V material region further provides a solid source for overpressure provided on the substrate surface during the subsequent annealing process, which also helps to suppress the decomposition Group III-V compound. While the invention is described mostly in the context of Group III-V, the general concept of the invention may be beneficial in the case of treatment of multiple compound semiconductor materials as discussed previously. The general concept of the invention may also be applicable to growth of other semiconductors on dissimilar substrates, or for improvement of film properties once grown.

While the foregoing is directed to embodiments of the present invention, other and further embodiments of the invention may be devised without departing from the basic scope thereof, and the scope thereof is determined by the claims that follow.

1. A method of manufacturing a compound semiconductor, comprising:
growing a compound semiconductor layer having a n-type or p-type dopant over a substrate, the compound semiconductor layer comprising at least a first component and a second component, and the second component has a vapor pressure relatively higher than the first component;
forming a supplemental layer consisted essentially of the second component at or near an upper surface of the compound semiconductor layer; and
subjecting the substrate to an annealing process.

2. The method of claim 1, further comprising:
a capping layer formed on the supplemental layer, the capping layer comprising SiN, SiO₂, Si, GaN, or AlN.

3. The method of claim 1, further comprising:
providing an overpressure of the second component gas onto an exposed surface of the substrate during the annealing process.

4. The method of claim 1, further comprising:
a n-doped or p-doped buffer layer formed in between the substrate and the compound semiconductor layer.

5. The method of claim 1, wherein the compound semiconductor layer comprises Group III-V or Group II-VI compound semiconductors.

6. The method of claim 1, wherein the supplemental layer is formed by a plasma immersion implantation process.

7. The method of claim 1, wherein the supplemental layer is formed by implanting atoms of the second component into the upper surface of the compound semiconductor layer at an ion implantation energy of about 5 keV to about 5000 keV.

8. The method of claim 7, wherein the supplemental layer has a total concentration of about 10¹¹ ions/cm² to about 10²¹ ions/cm².

9. The method of claim 1, wherein the annealing process is performed by directing a plurality of pulses of electromagnetic energy at the compound semiconductor layer or the buffer layer for a period of time that is sufficient to recrystallize the compound semiconductor layer.

10. The method of claim 9, wherein each pulse has the same energy of about 0.2 J/cm² to about 100 J/cm² and the same duration of about 1 nanosecond to about 1 second.

11. The method of claim 10, wherein the plurality of pulses of electromagnetic energy is delivered at a wavelength ranging between about 300 nm and about 1100 nm.

12. A method of manufacturing a compound semiconductor, comprising:
epitaxially growing a compound semiconductor layer having a p-type dopant over a substrate, the compound semiconductor layer comprising at least a first component and a second component, wherein the second component has a vapor pressure relatively higher than a vapor pressure of the first component;
forming a supplemental layer consisted essentially of the second component at or near an upper surface of the compound semiconductor layer; and
annealing the substrate with an overpressure of the second component gas provided onto an exposed surface of the substrate.

13. The method of claim 12, further comprising:
a capping layer formed on the supplemental layer, wherein the capping layer comprises SiN, SiO₂, Si, GaN, or AlN.

14. The method of claim 12, wherein the supplemental layer is formed by a plasma immersion implantation process.

15. The method of claim 12, wherein the annealing is performed by directing a plurality of pulses of electromagnetic energy at the compound semiconductor layer for a period of time that is sufficient to recrystallize the compound semiconductor layer.

16. A method of manufacturing a compound semiconductor, comprising:
growing a Group III-V compound semiconductor layer over a substrate;
forming a p-type doping layer on an upper surface of the Group III-V compound semiconductor layer;
forming a supplemental layer consisted essentially of Group V material on the p-type doping layer;
forming a capping layer on the supplemental layer; and
subjecting the substrate to an annealing process.

17. The method of claim 16, further comprising:
providing an overpressure of the second component gas onto an exposed surface of the substrate during annealing.

18. The method of claim 16, wherein the supplemental layer is formed by a plasma immersion implantation process.

19. The method of claim 16, wherein the capping layer comprises SiN, SiO₂, Si, GaN, or AlN.

20. The method of claim 16, wherein the annealing process is performed by directing a plurality of pulses of electromagnetic energy at the Group III-V compound semiconductor layer for a period of time that is sufficient to recrystallize the Group Ill-V compound semiconductor layer.

21. A compound semiconductor device, comprising:
a Group III-V compound semiconductor layer deposited over a substrate;
a p-type doping layer deposited on an upper surface of the Group III-V compound semiconductor layer;
a supplemental layer consisted essentially of Group V material deposited on the p-type doping layer; and
a capping layer deposited on the supplemental layer.

22. The device of claim 21, wherein the Group III-V compound semiconductor layer comprises GaN, GaAs, InSb, InAs, InP, GaSb, GaP, or AlSb

23. The device of claim 21, wherein the Group III-V compound semiconductor layer is a p-type doped Group III nitride.

24. The device of claim 21, wherein the capping layer comprises SiN, SiO₂, Si, GaN, or AlN.
